(19) United States
(12) Patent Application Publication
(10) Pub. No.: US 2015/0325712 A1
(43) Pub. Date: Nov. 12, 2015

(54) Nanostructured Thin-Film Solar Cell

(71) Applicants: Inna KOZINSKY, Mountain View, CA (US); ROBERT BOSCH GMBH, Stuttgart (DE)

(72) Inventor: Inna Kozinsky, Mountain View, CA (US)

(21) Appl. No.: 14/651,063

(22) PCT Filed: Dec. 10, 2013
(86) PCT No.: PCT/US2013/074032

§ 371 Date: Jun. 10, 2015

Related U.S. Application Data
(60) Provisional application No. 61/735,198, filed on Dec. 10, 2012.

(51) Int. Cl. H01L 31/0236; H01L 31/0352; H01L 31/18; H01L 31/0224

(52) U.S. Cl. CPC H01L 31/02363; H01L 31/022466; H01L 31/022475; H01L 31/022483; H01L 31/035209; H01L 31/1828; H01L 31/1884

(57) ABSTRACT

A nanostructured thin-film solar cell in one embodiment includes a photovoltaic absorber including a plurality of nanocones, each of the nanocones defining a longitudinal axis which extends through a first surface of the nanocone and a second surface of the nanocone, a translucent conductive coating positioned above the first surfaces of the photovoltaic absorber nanocones, and a conductive layer positioned on the second surfaces of the photovoltaic absorber nanocones.

This application claims priority under 35 U.S.C. §119 to U.S. Provisional Application No. 61/735,198, filed on Dec. 10, 2012, the disclosure of which is incorporated herein by reference in its entirety.

### FIELD

This disclosure relates to solar cells and more particularly to thin-film solar cells.

### BACKGROUND

The wealth of the United States has been created largely through the exploitation of cheap energy provided by the abundance of fossil fuels. The continued reliance on oil suppliers located in volatile regions, the approaching worldwide shortages of oil, and because of the growing danger of global warming that may be caused by the combustion of fossil fuels, clean reliable sources of renewable energy are needed.

Other efforts to develop power generation systems fueled by renewable energy sources have been focused on solar energy. The preponderance of currently available photovoltaic production is focused upon the use of crystalline silicon modules. Wafer based silicon modules incur an estimated cost of about $1-1.50/W with the cost of materials alone being about $0.30/W. The U.S. Department of Energy, however, has established a target of $0.50/W for utility scale applications for PV to become a viable competitor with fossil fuels. Accordingly, wafer based silicon modules are not good candidates to reach the low price necessary to compete with fossil fuels and meet the world energy demand.

Thin-film solar cells offer an inexpensive alternative to crystalline silicon solar cells. The relatively low efficiencies of thin-film cells, however, are preventing them from gaining a significant share of the solar energy market. By way of example, the efficiencies of thin-film modules are typically about 10% for thin-film Si, 12-13% for Cu(InGa)Se₂ (CIGS) thin films, and around 12% for CdTe modules. These technologies need at least 2-3% absolute efficiency gain in order to compete with the more expensive wafer-based Si photovoltaic (PV) modules which exhibit 15% efficiency or more.

One of the main causes of low efficiency in thin-film PV modules is low light absorption. Low light absorption results from reflection at the front transparent conducting oxide (TCO) and absorber interface, sub-optimal light-trapping by the absorber, and parasitic absorption of blue and near-IR light by the TCO. The TCO-absorber interface texture in current commercial cells is a function of the texture of the TCO as grown (thin-film Si) or by the texture of the absorber as grown (CIGS). The ability to optimize the interface texture is very limited because the texture structure results from the growth parameters, which affect the thickness and electrical properties of the absorber.

The ability to mitigate parasitic absorption by the TCO is likewise limited. Commercial modules typically include substrates of over 1 m². In order to ensure adequate conduction across such a large surface, relatively thick (>1.5 μm) TCO layers are required. Parasitic absorption, however, increases as the thickness of the TCO increases.

Efforts to ameliorate the absorption losses in PV modules are complicated by the fact that the contribution of components to absorption losses varies as a function of the particular wavelength of the incoming light. FIG. 1 depicts a chart 10 of the distribution of absorption losses in state-of-the-art tandem (micromorph) thin-film silicon cells. In FIG. 1, the absorption loss contribution of the glass covering the TCO is indicated by the line 12. The absorption loss contribution of the front TCO is indicated by the line 14, the absorption loss contribution of the amorphous silicon is indicated by the line 16, the absorption loss contribution of the microcrystalline silicon is indicated by the line 18, and the absorption loss contribution of the back TCO is indicated by the line 20.

FIG. 2 depicts a chart 30 of the distribution of absorption losses in state-of-the-art CIGS cells. In FIG. 2, the absorption loss contribution of the front TCO is indicated by the line 32, the absorption loss contribution of the cadmium sulfide is indicated by the line 34, and the absorption loss contribution of the CIGS is indicated by the line 36. FIG. 2 further includes a line 38 which indicates the absorption of a typical CIGS module without any light trapping or anti-reflection materials.

What is needed therefore is a thin-film PV module that exhibits increased efficiencies compared to known thin-film PV modules.

### SUMMARY

In one embodiment of the disclosure, a nanostructured thin-film solar cell includes a photovoltaic absorber including a plurality of nanocones, each of the nanocones defining a longitudinal axis which extends through first surface of the nanocone and a second surface of the nanocone, a translucent conductive coating positioned above the first surfaces of the photovoltaic absorber nanocones, and a conductive layer positioned on the second surfaces of the photovoltaic absorber nanocones. In some embodiments, a transparent conductive coating is used.

In some embodiments, the translucent conductive coating is conformally deposited on the first surfaces of the photovoltaic absorber nanocones. The nanostructured thin-film solar cell of some embodiments includes a translucent conductive coating including one or more of aluminum-doped zinc oxide (ZnO:Al), F-doped tin oxide (FTO), indium tin oxide (ITO), In₂O₃:Ti, p-CuZnS, and CdSnO₂. In some of the embodiments, the translucent conductive coating includes a glass layer; and a grid of first nanostructured conductors, the grid of first nanostructured conductors contacting the first surfaces of the photovoltaic absorber nanocones. The nanostructured thin-film solar cell in some embodiments includes a grid of first nanostructured conductors dip-coated to a glass layer. In one or more embodiments, the nanostructured thin-film solar cell includes a grid of nanowires. In some embodiments, the nanostructured thin-film solar cell includes a photovoltaic absorber including one or more of silicon, copper indium gallium sulfide/selenide (CIGS), cadmium telluride (CdTe), copper zinc tin sulfide/selenide (CZTS/CZTSe), cuprous oxide, and tin sulfide. In some embodiments, a transparent conductive coating is used.

In another embodiment, a method of forming a nanostructured thin-film solar cell includes forming a plurality of nanocones using a photovoltaic material, each of the nanocones defining a longitudinal axis which extends through a first surface of the nanocone and a second surface of the nanocone, positioning a translucent conductive coating above the first surfaces of the photovoltaic absorber nanocones, and positioning a conductive layer on the second surfaces of the photovoltaic absorber nanocones.

In another embodiment, a method of forming a nanostructured thin-film solar cell includes forming a plurality of optimally sized nanocones on the underlying substrate or superstrate, so that the tapered sub-micron structure is transferred to the subsequent photovoltaic absorber layers.

In another embodiment, a nanostructured thin-film solar cell includes a substrate textured with sub-micron tapered nanostructures, photovoltaic absorber textured by a plurality of nanocones or nanostructures optimized to reduce reflection at the interface between the absorber and adjacent layer, and transparent conductive layers on both sides of the photovoltaic absorber.

### BRIEF DESCRIPTION OF DRAWINGS

FIG. 1 depicts a chart indicating the contributions to absorption loss of various components in a prior art amorphous silicon/microcrystalline silicon PV module;

FIG. 2 depicts a chart indicating the contributions to absorption loss of various components in a prior art CIGS PV module;

FIG. 3 depicts a partial cross section of a PV module with a nanostructured substrate and nanowire grid electrode;

FIG. 4 depicts a top perspective view of a portion of the PV absorber of FIG. 3; and

FIG. 5 depicts a top plan view of a portion of the nano-fiber/nano-wire electrode of FIG. 3.

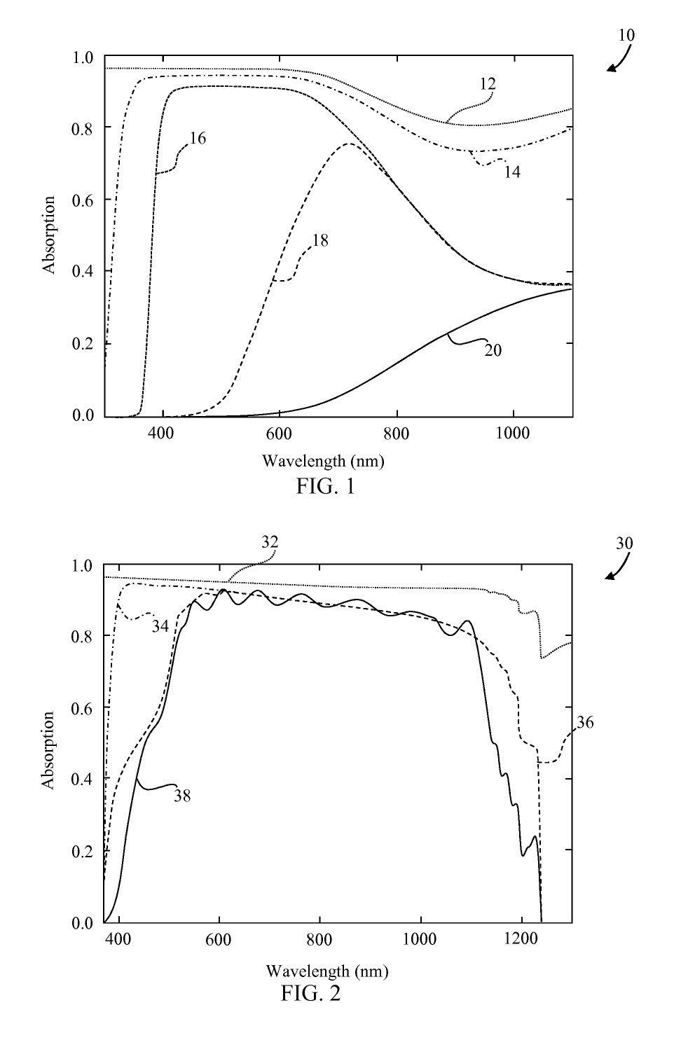

### DETAILED DESCRIPTION

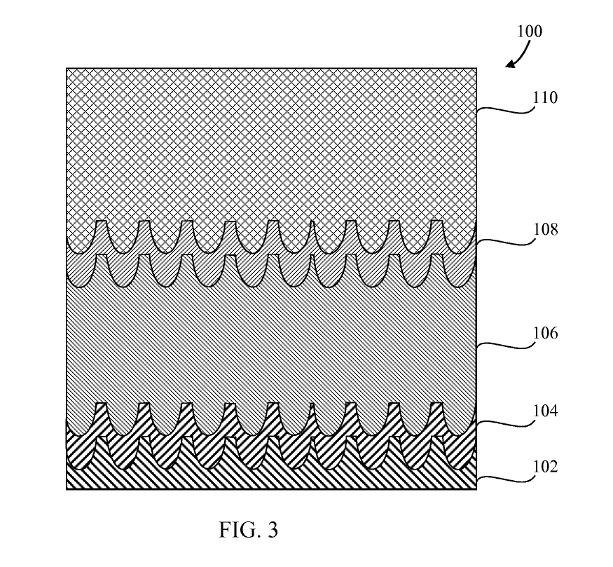

FIG. 3 depicts a partial cross-sectional view of a thin-film photovoltaic (PV) module 100. The module 100 includes a substrate layer 102, a nano-fiber/nano-wire grid 104, a PV absorber 106, a second nano-fiber/nano-wire grid 108 and a glass layer 110. The glass layer 110 and the nano-fiber/nano-wire grid 104 form a translucent conductive coating which is depicted as being conformal with the absorber 106 in FIG. 3, but in some embodiments is non-conformal. In some embodiments, a transparent conductive coating is used.

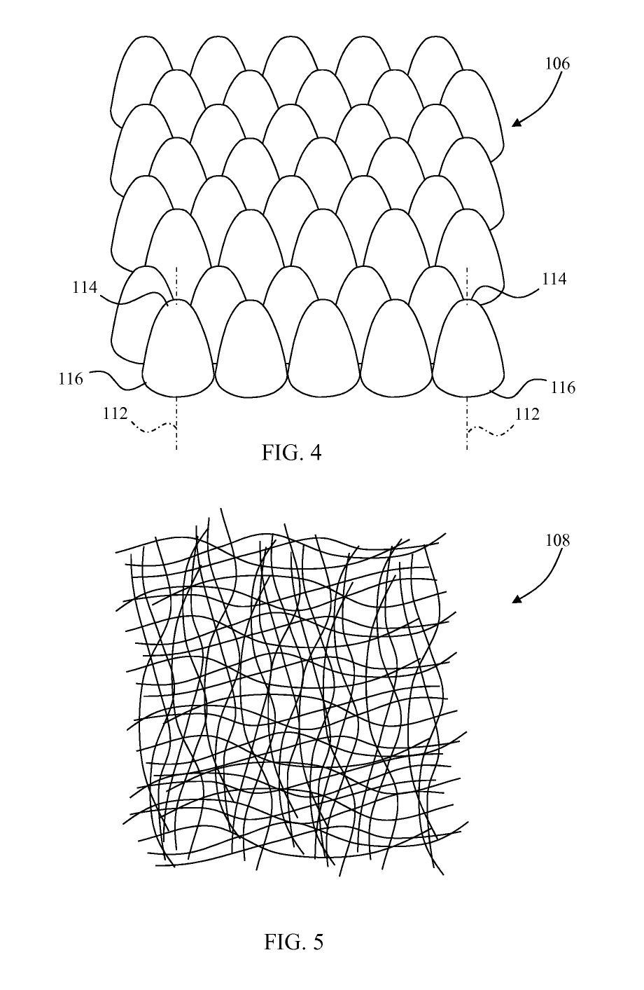

The PV absorber 106 is formed as a nanocone substrate as depicted in FIG. 4. Each of the nanocones 106 define a longitudinal axis 112 which extends through an first surface 114 of the nanocone and a second surface 116 of the nanocone 106. Each of the longitudinal axes 112 are substantially parallel to the other of the longitudinal axes.

The nanocone absorber 106 in one embodiment is formed using a method described by Zhu et al., “Nanostructured photon management for high performance solar cells,” Materials Science and Engineering R, 70 (2010) pp. 330-340. The process disclosed by Zhu et al. is a large scale/low temperature process that provides precise control of diameters, spacing and shapes across a wide range, from tens of nanometers to several microns. In general, monodisperse SiO₂ nanoparticles are assembled into a close-packed monolayer on top of a silicon wafer using the Langmuir-Blodgett (LB) assembly. Monodisperse SiO₂ particles, with diameters from 50 to 800 nm, are produced by a modified Stöber synthesis. The particles are modified with aminopropyldiethoxymethylsilane so as to terminate them with positively charged amine groups, preventing aggregation. The diameter and spacing of the nanoparticles can be further tuned by selective and isotropic reactive ion etching (RIE) of the SiO₂. The RIE etching is based on fluorine chemistry, using a mixture of O₂ and CHF₃. Si nanowires and nanocones can similarly be obtained by using Cl₂ based selective and anisotropic RIE. The diameter and spacing of these nanostructures are determined by the initial nanoparticle sizes and both SiO₂ and Si etching times. SiO₂ particles can be removed by hydrofluoric acid (HF), if needed. In some embodiments, nanocones or other reflection-reducing nanostructures at the solar cell interfaces are fabricated by lithography methods, selective or random etching of the substrate or superstrate, nanoimprinting, or other nanotexturing techniques.

The nanostructured light-trapping nanocone absorber 106 in different embodiments is incorporated into different thin-film PV cells such as thin-film Si, CIGS, CdTe, CZTS, Cu₂O, SnS, CdTe, and other thin-film PV materials. The form of the nanocone absorber 106 enhances the absorption of the nanocone absorber 106 by up to 20-30%, adding up to 3% to the absolute efficiency of the module 100, as compared to traditionally formed absorbers. In different embodiments, the nanocone absorber 106 is used as a front substrate for PV cells deposited in superstrate configuration (e.g. current thin-film Si modules) or back substrates for PV cells deposited in substrate configuration (e.g. current CIGS and CdTe modules).

The term “superstrate” refers to a solar cell configuration where the transparent substrate (typically glass) is not only used as supporting structure but also as window for the illumination and as part of the encapsulation. During operation the glass is “above” the absorber. In “substrate” configurations, the glass (or other supportive substrate) is located beneath the absorber. In other words, the front TCO in a superstrate configuration is located between the substrate layer and the buffer layer so that light first passes through the glass before passing through the front TCO. In a substrate configuration, the front TCO is directly subjected to incoming light.

The nanocone absorber 106 reduces the losses due to sub-optimal light management in the module 100 by optimized nanoscale texturing. The advantage of optimized texture is to combine the reduction of reflection of short-wavelength light with maximized light-trapping for long-wavelength light. This is achieved in the embodiment of FIG. 3 by further grading the index of refraction between the substrate 102 and the absorber 106 using sub-wavelength texturing and ensuring maximal coupling to guided modes in the thin-film absorber layer 106 using textures with optimized period, height, and fill factor. The particular form of the cones, including height, spacing, diameter, etc., will thus vary depending upon the particular application.

The nano-fiber/nano-wire grids 104/106 are grids of conductive nanostructures which function as electrodes for current formed in the absorber 106 when the absorber 106 is subjected to light. The nano-fiber/nano-wire grids 104/106 replace the TCO of prior art devices with a transparent or translucent layer with high conductivity which is achieved by dip coating a glass substrate (glass layer 110) in a solution of nanowires to create a grid or mesh of conductive nanowires or nanofibers on the glass substrate. Alternatively, the nanowires can be deposited or grown directly on the substrate surface with or without the use of a fugitive catalyst. One method for forming the nano-fiber/nano-wire grids 104/106 is disclosed by Wu, et al., “Electrospun Metal Nanofiber Wbs as High-Performance Transparent Electrode,” Nano Letters 10, pp. 4242-4248 (2010).

As discussed by Wu et al., electrical sheet resistance and optical transmittance are two of the main criteria for transparent conducting electrodes in optoelectronic devices. Wu et al. disclose the incorporation of a mesoscale metal wire (1-5 μm in diameter) into metal nanowire transparent conducting electrodes resulting in at least a one order of magnitude reduction in sheet resistance at a given transmittance. The resulting hybrid of mesoscale and nanoscale metal nanowires provide high performance, including a sheet resistance of 0.36 Ω sq−1 and transmittance of 92%.

The nano-fiber/nano-wire grids 104/106 decrease parasitic absorption in the TCO by providing metallic conduction. Plasmonic effects in thin metal wires is used in some embodiments to further enhance light absorption, allowing for flatter textures and enabling the growth of better quality absorber films.

In another embodiment, standard TCO can be replaced by a thin layer of improved transparent conducting materials with high mobility and low near-IR absorption (e.g., In₂O₃:Ti, p-CuZnS, CdSnO₂), conformally deposited on the textured substrate using Atomic Layer Deposition (ALD) techniques.

Accordingly, the module 100 exhibits increased efficiency, while providing a thinner cross section by use of textured absorber interfaces and thinner TCO layers.

While the invention has been illustrated and described in detail in the drawings and foregoing description, the same should be considered as illustrative and not restrictive in character. Only the preferred embodiments have been presented and all changes, modifications and further applications that come within the spirit of the invention are desired to be protected.

What is claimed is:

1. A nanostructured thin-film solar cell, comprising:
a photovoltaic absorber including a plurality of nanocones, each of the nanocones defining a longitudinal axis which extends through a first surface of the nanocone and a second surface of the nanocone;
a translucent conductive coating positioned above the first surfaces of the photovoltaic absorber nanocones; and
a conductive layer positioned on the second surfaces of the photovoltaic absorber nanocones.

2. The nanostructured thin-film solar cell of claim 1, wherein the translucent conductive coating is conformally deposited on the first surfaces of the photovoltaic absorber nanocones.

3. The nanostructured thin-film solar cell of claim 2, wherein the translucent conductive coating comprises a material selected from a group consisting of:
aluminum-doped zinc oxide (ZnO:Al);
indium tin oxide (ITO);
fluorine-doped tin oxide (FTO);
In₂O₃:Ti;
p-CuZnS; and
CdSnO₂.

4. The nanostructured thin-film solar cell of claim 1, wherein the translucent conductive coating comprises:
a glass layer; and
a grid of first nanostructured conductors, the grid of nanostructured conductors contacting the first surfaces of the photovoltaic absorber nanocones.

5. The nanostructured thin-film solar cell of claim 4, wherein the grid of nanostructured conductors is dip-coated to the glass layer.

6. The nanostructured thin-film solar cell of claim 5, wherein the grid of nanostructured conductors comprises a grid of nanowires.

7. The nanostructured thin-film solar cell of claim 6, wherein the photovoltaic absorber comprises one or more materials selected from the group consisting of:
silicon;
copper indium gallium selenide;
cadmium telluride;
copper zinc tin sulfide;
cuprous oxide; and
tin sulfide.

8. The nanostructured thin-film solar cell of claim 6, wherein the conductive layer comprises a grid of nanowires.

9. A method of forming a nanostructured thin-film solar cell comprising:
forming a plurality of nanocones using a photovoltaic material, each of the nanocones defining a longitudinal axis which extends through a first surface of the nanocone and a second surface of the nanocone;
positioning a translucent conductive coating above the first surfaces of the photovoltaic absorber nanocones; and
positioning a conductive layer on the second surfaces of the photovoltaic absorber nanocones.

10. The method of claim 9, wherein positioning the translucent conductive coating above the first surfaces comprises:
conformally depositing the translucent conductive coating on the first surfaces of the photovoltaic absorber nanocones.

11. The method of claim 10, wherein conformally depositing the translucent conductive coating comprises:
conformally depositing a material selected from a group consisting of:
aluminum-doped zinc oxide (ZnO:Al);
indium tin oxide (ITO);
fluorine-doped tin oxide (FTO);
In₂O₃:Ti;
p-CuZnS; and
CdSnO₂.

12. The method of claim 9, further comprising:
forming the translucent conductive coating with a glass layer and a grid of first nanostructured conductors, wherein positioning the translucent conductive coating above the first surfaces comprises:
contacting the first surfaces of the photovoltaic absorber nanocones with the grid of first nanostructured conductors.

13. The method of claim 12, wherein forming the translucent conductive coating further comprises:
dip-coating the grid of first nanostructured conductors to the glass layer.

14. The method of claim 13, wherein forming the translucent conductive coating further comprises:
dip-coating a grid of nanowires to the glass layer.

15. The method of claim 9, wherein forming the plurality of nanocones using a photovoltaic material comprises;
forming the plurality of nanocones using a photovoltaic material selected from the group consisting of:
silicon;
copper indium gallium selenide;
cadmium telluride;
copper zinc tin sulfide;
cuprous oxide; and
tin sulfide.

16. A nanostructured thin-film solar cell, comprising:
a photovoltaic absorber with optimally nanotextured interfaces, enabled by nanocone or other sub-micron tapered shapes on the substrates;
a transparent conductive layer on the top and bottom of the absorber layer to carry the current; and
a substrate or superstrate for the solar cell that can carry the texture propagating into the cell layers.

17. The nanostructured thin-film solar cell of claim 16, wherein the transparent conductive coating is conformally deposited on the first surfaces of the photovoltaic absorber nanocones.

18. The nanostructured thin-film solar cell of claim 17, wherein the transparent conductive coating comprises a material selected from a group consisting of:
aluminum-doped zinc oxide (ZnO:Al);
indium tin oxide (ITO);
fluorine-doped tin oxide (FTO);
In2O3:Ti;
p-CuZnS; and
CdSnO2.

19. The nanostructured thin-film solar cell of claim 16, wherein the transparent conductive coating comprises:
a glass layer; and
a grid of first nanostructured conductors, the grid of nanostructured conductors contacting the first surfaces of the photovoltaic absorber nanocones.

20. The nanostructured thin-film solar cell of claim 19, wherein the grid of nanostructured conductors is dip-coated to the glass layer.
